(19) United States
(12) Patent Application Publication
(10) Pub. No.: US 2020/0235662 A1
(43) Pub. Date: Jul. 23, 2020

(54) DC-TO-DC CONVERTER HAVING AN INDUCTIVE CONDUCTOR

(71) Applicant: GM GLOBAL TECHNOLOGY OPERATIONS LLC, Detroit, MI (US)

(72) Inventors: Alan G. Holmes, Clarkston, MI (US); Kris Sevel, Rochester Hills, MI (US); Alireza Fatemi, Canton, MI (US)

(21) Appl. No.: 16/253,530

(22) Filed: Jan. 22, 2019

(51) Int. Cl. H02M 3/155; B60R 16/02; H05K 7/20

(52) U.S. Cl. CPC H02M 3/155; B60R 16/02; H05K 7/20863; H05K 7/20909; H05K 7/20172

(57) ABSTRACT

In one example implementation according to aspects of the present disclosure, a DC-to-DC converter for transmitting electricity from a first power device at a first voltage and current combination to a second power device at a second voltage and current combination is provided. The DC-to-DC converter comprises a first electrical conductor having a first end and a second end and a second electrical conductor having a third end and a fourth end. The first end and the third end are electrically coupled to the first power device and the second end and the fourth end are electrically coupled to the second power device. The first electrical conductor and the second electrical conductor together provide circuit inductance substantially equivalent to and in place of an inductor having a circular winding.

### INTRODUCTION

The present disclosure relates to a direct current (DC)-to-DC converter having an inductive conductor.

A DC-to-DC converter uses one or more electrical conductors that carry current from one device to another device. For example, a first electric vehicle (e.g., a car, a motorcycle, a boat, or any other type of automobile) may be coupled to a second electric vehicle (e.g., a car, a motorcycle, a boat, or any other type of automobile) using a DC-to-DC converter to cause one or more batteries of the first electric vehicle to charge one or more batteries of the second electric vehicle. In another example, two power devices (i.e., electric components) within a vehicle can be coupled together using a DC-to-DC converter to transfer power from one of the power devices to the other of the power devices.

### SUMMARY

In one exemplary embodiment, a direct current (DC)-to-DC converter transmitting electricity from a first power device at a first voltage and current combination to a second power device at a second voltage and current combination is provided. The DC-to-DC converter includes a first electrical conductor having a first end and a second end a second electrical conductor having a third end and a fourth end. The first end and the third end are electrically coupled to the first power device and the second end and the fourth end are electrically coupled to the second power device. The first electrical conductor and the second electrical conductor together provide circuit inductance substantially equivalent to and in place of an inductor having a circular winding.

In additional examples, the first power device is disposed in a first electric vehicle, the second power device is disposed in a second electric vehicle, and the DC-to-DC converter facilitates charging of the second power device disposed in the second electric vehicle. In additional examples, the first power device is disposed in a first location of a vehicle, the second power device is disposed in a second location of the vehicle, and the DC-to-DC converter facilitates providing electricity from the first power device to the second power device. In additional examples, a length of the first electrical conductor is determined based on an inductance value of the inductor with a circular winding. In additional examples, the first end and the third end are disposed in a first housing. In additional examples, the first housing includes a first fan configured to force air over a first heatsink disposed in the first housing to cool at least a portion of the first electrical conductor and the second electrical conductor. In additional examples, the second end and the fourth end are disposed in a second housing. In additional examples, the second housing includes a second fan configured to force air over a second heatsink disposed in the second housing to cool at least a portion of the first electrical conductor and the second electrical conductor. In additional examples, the first electrical conductor and the second electrical conductor are coaxially arranged. In additional examples, the first electrical conductor comprises iron alloy. In additional examples, the first electrical conductor comprises ferrite rings. In additional examples, the first electrical conductor comprises fine iron wires insulated from one another.

In another exemplary embodiment, a system includes a first vehicle having a first power device, a second vehicle having a second power device, and a direct current (DC)-to-DC converter. The DC-to-DC converter includes a first electrical conductor having a first end and a second end a second electrical conductor having a third end and a fourth end. The first end and the third end are electrically coupled to the first power device and the second end and the fourth end are electrically coupled to the second power device. The first electrical conductor and the second electrical conductor together provide circuit inductance substantially equivalent to and in place of an inductor having a circular winding.

In additional examples, a length of the first electrical conductor is determined based on an inductance value of the inductor with a circular winding. In additional examples, the first electrical conductor and the second electrical conductor are coaxially arranged. In additional examples, the first electrical conductor comprises iron alloy. In additional examples, the first electrical conductor comprises ferrite rings. In additional examples, the first electrical conductor comprises fine iron wires insulated from one another.

In another exemplary embodiment, a vehicle includes a first power device, a second power device, and a direct current (DC)-to-DC converter. The DC-to-DC converter includes a first electrical conductor having a first end and a second end a second electrical conductor having a third end and a fourth end. The first end and the third end are electrically coupled to the first power device and the second end and the fourth end are electrically coupled to the second power device. The first electrical conductor and the second electrical conductor together provide circuit inductance substantially equivalent to and in place of an inductor having a circular winding.

In additional examples, a length of the first electrical conductor is determined based on an inductance value of the inductor with a circular winding.

The above features and advantages, and other features and advantages, of the disclosure are readily apparent from the following detailed description when taken in connection with the accompanying drawings.

### BRIEF DESCRIPTION OF THE DRAWINGS

Other features, advantages, and details appear, by way of example only, in the following detailed description, the detailed description referring to the drawings in which:

FIG. 1A depicts a DC-to-DC converter electrically coupling a first power device of a first vehicle and a second power device of a second vehicle according to one or more embodiments described herein;

FIG. 1B depicts a DC-to-DC converter electrically coupling a first power device and a second power device of a first vehicle according to one or more embodiments described herein;

FIG. 2A depicts the DC-to-DC converter of FIGS. 1A and 1B according to one or more embodiments described herein;

FIG. 2B depicts a coaxial DC-to-DC converter according to one or more embodiments described herein;

FIGS. 2C and 2D depict cross-sectional views of the coaxial DC-to-DC converter of FIG. 2B according to one or more embodiments described herein; and

FIG. 3 depicts the DC-to-DC converter of FIGS. 1A and 1B electrically coupling a first circuit to a second circuit according to one or more embodiments described herein.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The technical solutions described herein provide for using a DC-to-DC converter having an inductive conductor to enable electricity transmitted from a first power device to a second power device to be converted from a first voltage and current combination to a second voltage and current combination. Vehicles, especially electric vehicles, utilize one or more batteries to supply power to components, such as motors, electronics, and the like within the vehicle. As described herein, the term “power device” is used to describe devices, components, modules, etc., that supply, store, condition, and/or consume power. According to one or more embodiments described herein, power is supplied between a first power device (e.g., a battery) in one location in the vehicle and a second power device (e.g., a power inverter) in another part of the vehicle. According to one or more embodiments described herein, power is supplied between a first power device (e.g., a first battery) in a first vehicle and a second power device (e.g., a second battery) in a second vehicle.

In particular, the present techniques utilize a DC-to-DC converter that includes one or more electrical conductors that carry current from one power device to another power device as an inductor so that the converter does not need or contain a discrete inductor (i.e., an inductor having a circular winding). For example, a vehicle-to-vehicle DC-to-DC charge cable set or an electric vehicle power system can utilize the DC-to-DC converter of the present techniques. The presently described DC-to-DC converter that uses an inductive conductor eliminates the need for a discrete inductor, which reduces mass, size, cost, and conduction losses of inductors in traditional DC-to-DC converters currently in use. According to one or more embodiments described herein, the present techniques provide a DC-to-DC conductor to exchange power from one power device to another power device using the conductors between devices as the inductor, which can be accomplished by: (1) paired conductors with mechanically-defined spacing; (2) conductors with magnetically permeable material around one (or both) conductors; and/or (3) conductors of magnetically permeable material, such as iron wire. The principles of the present techniques can be applied to cables of a vehicle-to-vehicle DC charger or a boost converter in an electric vehicle or hybrid electric vehicle, for example.

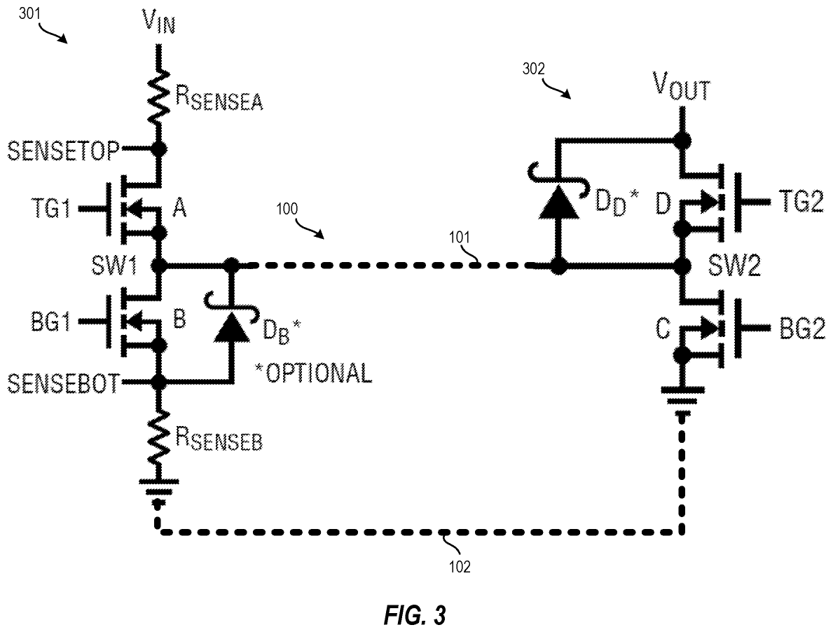

The present techniques enable construction of a DC-to-DC converter that causes current from an input to an output to flow through an inductor and utilizes a relatively low inductance to operate continuously. For example, a “synchronous’ DC-to-DC converter circuit (described with reference to FIG. 3 below), a buck-boost circuit, a pi circuit, a Cuk circuit, and the like, can implement the DC-to-DC converter described herein. Existing approaches utilize a separate inductor and conductor that are in electrical series with one another. However, the present techniques enable the separate inductor to be eliminated because the conductor performs the functions of both the conductor and the inductor. This may be referred to as an “inductor-conductor.”

According to one or more embodiments described herein, the inductor-conductor is separated from a return conductor by a fixed, non-zero distance by the construction of a two-conductor cable. According to other embodiments described herein, the separation between the inductor-conductor and the return conductor can vary and need not be constant/fixed. In such cases, the variation(s) in separation can be compensated for using a controller or other suitable circuitry. According to one or more embodiments described herein, the inductor-conductor is encircled by a material with a high relative magnetic permeability and low eddy current losses, such as an iron alloy (i.e., iron with minimal alloy content for the wire such as low-carbon steel), small ferrite rings, a hybrid of pure iron strands surrounding a core of purely conductive (e.g., copper) strands, etc. According to one or more embodiments described herein, the inductor-conductor is made from a single material that is electrically conductive, has relatively high magnetic permeability, and has low eddy current losses, such as a cable of fine iron wires insulated from one another (e.g., a Litz wire made of iron).

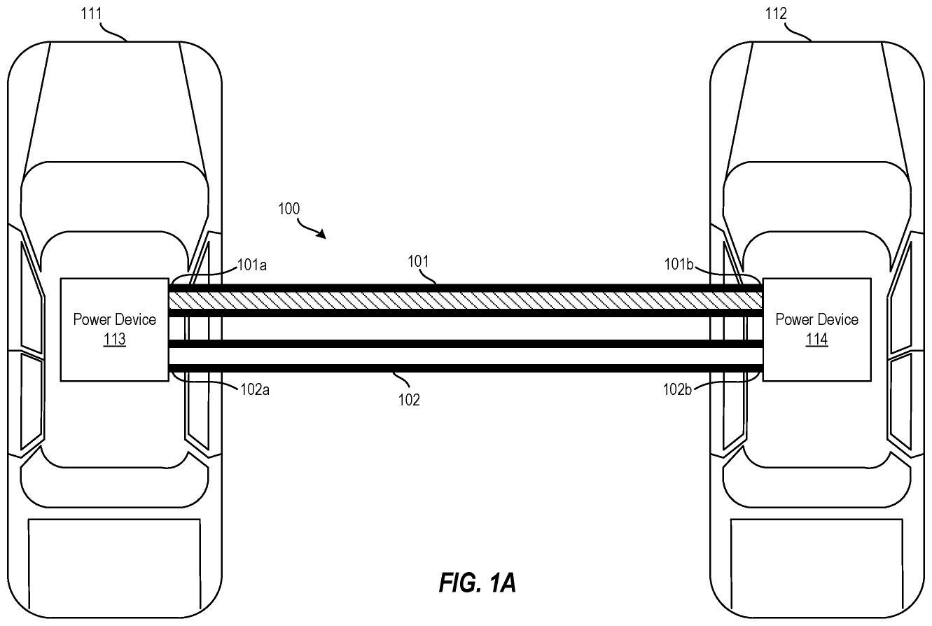

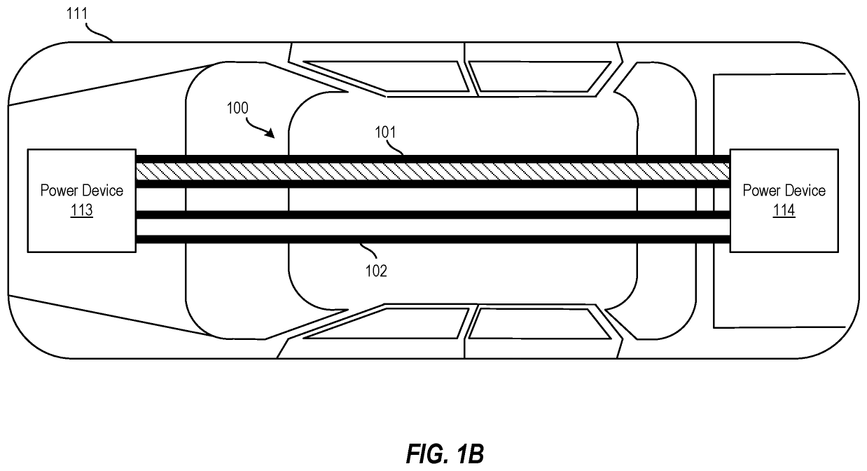

FIG. 1A depicts a DC-to-DC converter 100 electrically coupling a first power device 113 of a first vehicle 111 and a second power device 114 of a second vehicle 112 according to one or more embodiments described herein. As described above, the power devices 113, 114 can be any suitable electronic component, such as an electric motor, battery, etc. The power devices 113, 114 can include voltage boosting switching and capacitance devices integrated therein. For illustrative purposes, the power devices 113, 114 in the example of FIG. 1A are considered batteries. In such an example, the DC-to-DC converter 100 enables one of the power devices 113, 114 to charge the other of the power devices 113, 114. This is beneficial in the case where the vehicles 111, 112 are electric vehicles and/or hybrid electric vehicles.

The DC-to-DC converter 100 includes a first electrical conductor 101 (also referred to as an “inductor-conductor”) and a second electrical conductor 102 (also referred to as a “return conductor”). The first electrical conductor 101 includes a first end 101a and a second end 101b, and the second electrical conductor includes a third end 102a and a fourth end 102b. The first end 101a and the third end 102a are electrically coupled to the first power device 113, and the second end 101b and the fourth end 102b are coupled to the second power device 114.

Electricity is supplied, for example, by the power device 113 to the power device 114 via the DC-to-DC converter 100 utilizing the first electrical conductor 101 and the second electrical conductor 102. The first electrical conductor 101 provides an inductance that is substantially equivalent to an inductance that would be provided by a circular winding. This enables the first electrical conductor 101 to replace a traditional inductor having a circular winding, thereby reducing mass, size, cost, complexity, and conduction losses in the DC-to-DC converter 100. According to one or more embodiments described herein, the DC-to-DC converter 100 can have a length that is determined based on an inductance value of a traditional inductor with a circular winding so that the traditional inductor with circular winding can be eliminated and replaced by the first electrical conductor 101 of the DC-to-DC conductor 100.

The DC-to-DC converter 100 serves as a device to transfer high-power DC electricity while converting it from one voltage and current combination to another. This is accomplished by using the inductance in the transfer conductor (e.g., the first electrical conductor 101) to effect the conversion of DC electricity without a discrete inductor with a circular winding.

According to one or more embodiments described herein, the DC-to-DC converter 100 incorporates material(s) with a relatively high magnetic permeability and low losses, such as steel wire or ferrite, into a conductor (e.g., the first electrical conductor 101) for effecting the transfer of energy from the first power device 113 at one voltage to the second power device 114 at a greater voltage.

FIG. 1B depicts a DC-to-DC converter 100 electrically coupling a first power device 113 and a second power device 114 of a first vehicle 111 according to one or more embodiments described herein. In this example, the first power device is disposed in a first location of the vehicle (e.g., near the front of the vehicle), and wherein the second power device is disposed in a second location of the vehicle (e.g., near the rear of the vehicle). In such cases, the DC-to-DC converter 100 facilitates providing electricity from the first power device 113 to the second power device 114 within the vehicle 111. Accordingly, the DC-to-DC converter 100 acts as a cable used as inductance for regulating (buck or boost) voltage. According to one or more embodiments described herein, the first vehicle 111 includes a DC-DC controller (not shown) that can dynamically adapt to changing inductance from potential movement of the DC-to-DC converter 100 as well as changing voltage during power transfer.

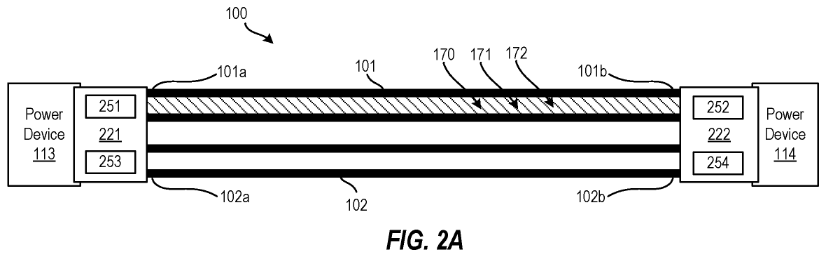

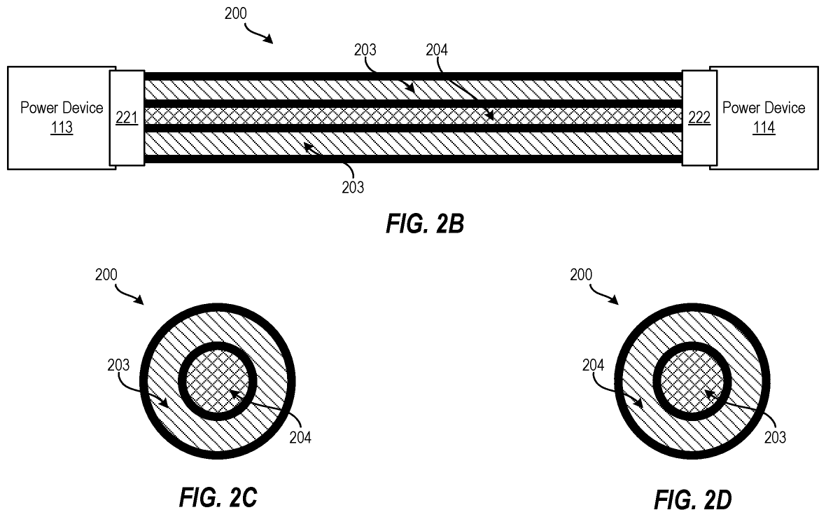

FIG. 2A depicts the DC-to-DC converter 100 of FIGS. 1A and 1B according to one or more embodiments described herein. In the example of FIG. 2A, the first electrical conductor 101 and the second electrical conductor 102 are separated from one another. The first electrical conductor 101 and the second electrical conductor 102 can be separated by a fixed distance, a non-zero distance, a variable distance, etc.

As described above, the DC-to-DC converter 100 includes a first electrical conductor 101 and a second electrical conductor 102. The first electrical conductor 101 includes a first end 101a and a second end 101b, and the second electrical conductor includes a third end 102a and a fourth end 102b. The first end 101a and the third end 102a are contained within a first housing 221 that electrically couples the first and third ends 101a, 102a to the first power device 113. Similarly, the second end 101b and the fourth end 102b contained within a second housing 222 that electrically couples the second and fourth ends 101b, 102b to the second power device 114.

The first housing 221 can include a first fan (not shown) that is configured to force air over a first heatsink (not shown) disposed in the first housing 221. This enables at least a portion of the first electrical conductor 101 and the second electrical conductor 102 to be cooled. Similarly, the second housing 222 can include a second fan (not shown) that is configured to force air over a second heatsink (not shown) disposed in the first housing 221. This enables at least a portion of the first electrical conductor 101 and the second electrical conductor 102 to be cooled.

FIG. 2B depicts a coaxial DC-to-DC converter 200 according to one or more embodiments described herein. In the example of FIG. 2, the coaxial DC-to-DC converter 200 includes a first electrical conductor 203 (i.e., an “inductor-conductor”) and a second electrical conductor 204 (i.e., a “return conductor”) arranged about an axis. This arrangement is further illustrated in FIG. 2C, which depicts a cross-sectional view of the coaxial DC-to-DC converter 200 of FIG. 2B according to one or more embodiments described herein. As can be seen, the first electrical conductor 203 can be formed around the second electrical conductor 204. In other examples, such as the example of FIG. 2D, the second electrical conductor 204 can be formed around the first electrical conductor 203. The coaxial DC-to-DC converter 200 may produce less magnetic interference than other DC-to-DC converters, such as the DC-to-DC converter 100.

FIG. 3 depicts the DC-to-DC converter 100 of FIGS. 1A and 1B electrically coupling a first circuit 301 to a second circuit 302 according to one or more embodiments described herein. In this example, together the first circuit 301 and the second circuit 302 form a synchronous DC-DC converter circuit. The first circuit 301 is disposed in one of the power devices (e.g., the first power device 113) and the second circuit 302 is disposed in another of the power devices (e.g., the second power device 114). The DC-to-DC converter 100 (or the DC-to-DC converter 200) is electrically coupled between the first circuit 301 and the second circuit 302 to “complete” the circuits. The first electrical conductor 101 provides an inductance between the first circuit 301 and the second circuit 302 that is substantially equivalent to (and in place of) an inductor having a circular winding. The second electrical conductor 102 acts as a return conductor between the first circuit 301 and the second circuit 302.

The descriptions of the various examples of the present disclosure have been presented for purposes of illustration but are not intended to be exhaustive or limited to the embodiments disclosed. Many modifications and variations will be apparent to those of ordinary skill in the art without departing from the scope and spirit of the described techniques. The terminology used herein was chosen to best explain the principles of the present techniques, the practical application or technical improvement over technologies found in the marketplace, or to enable others of ordinary skill in the art to understand the techniques disclosed herein.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present techniques not be limited to the particular embodiments disclosed, but will include all embodiments falling within the scope of the application.

1. A direct current (DC)-to-DC converter transmitting electricity from a first power device at a first voltage and current combination to a second power device at a second voltage and current combination, the DC-to-DC converter comprising:
a first electrical conductor having a first end and a second end; and
a second electrical conductor having a third end and a fourth end,
wherein the first end and the third end are electrically coupled to the first power device and wherein the second end and the fourth end are electrically coupled to the second power device,
wherein the first electrical conductor and the second electrical conductor together provide circuit inductance substantially equivalent to and in place of an inductor having a circular winding, and
wherein the first power device is disposed in a first location of a vehicle, and wherein the second power device is disposed in a second location of the vehicle.

2. The DC-to-DC converter of claim 1, wherein the first power device is disposed in a first electric vehicle, and wherein the second power device is disposed in a second electric vehicle, wherein the DC-to-DC converter facilitates charging of the second power device disposed in the second electric vehicle.

3. The DC-to-DC converter of claim 1, wherein the DC-to-DC converter facilitates providing electricity from the first power device in the vehicle to the second power device in the vehicle.

4. The DC-to-DC converter of claim 1, wherein a length of the first electrical conductor is determined based on an inductance value of the inductor with a circular winding.

5. The DC-to-DC converter of claim 1, wherein the first end and the third end are disposed in a first housing.

6. The DC-to-DC converter of claim 5, wherein the first housing comprises a first fan configured to force air over a first heatsink disposed in the first housing to cool at least a portion of the first electrical conductor and the second electrical conductor.

7. The DC-to-DC converter of claim 5, wherein the second end and the fourth end are disposed in a second housing.

8. The DC-to-DC converter of claim 7, wherein the second housing comprises a second fan configured to force air over a second heatsink disposed in the second housing to cool at least a portion of the first electrical conductor and the second electrical conductor.

9. The DC-to-DC converter of claim 1, wherein the first electrical conductor and the second electrical conductor are coaxially arranged.

10. The DC-to-DC converter of claim 1, wherein the first electrical conductor comprises iron alloy.

11. The DC-to-DC converter of claim 1, wherein the first electrical conductor comprises ferrite rings.

12. The DC-to-DC converter of claim 1, wherein the first electrical conductor comprises fine iron wires insulated from one another.

13. A system comprising:
a first vehicle having a first power device;
a second vehicle having a second power device; and
a direct current (DC)-to-DC converter transmitting electricity from the first power device at a first voltage and current combination to the second power device at a second voltage and current combination, the DC-to-DC converter comprising:
a first electrical conductor having a first end and a second end; and
a second electrical conductor having a third end and a fourth end,
wherein the first end and the third end are electrically coupled to the first power device of the first vehicle and wherein the second end and the fourth end are electrically coupled to the second power device of the second vehicle, and
wherein the first electrical conductor and the second electrical conductor together provide circuit inductance substantially equivalent to and in place of an inductor having a circular winding.

14. The system of claim 13, wherein a length of the first electrical conductor is determined based on an inductance value of the inductor with a circular winding.

15. The system of claim 13, wherein the first electrical conductor and the second electrical conductor are coaxially arranged.

16. The system of claim 13, wherein the first electrical conductor comprises iron alloy.

17. The system of claim 13, wherein the first electrical conductor comprises ferrite rings.

18. The system of claim 13, wherein the first electrical conductor comprises fine iron wires insulated from one another.

19. A vehicle comprising:
a first power device;
a second power device; and
a direct current (DC)-to-DC converter transmitting electricity from a first power device at a first voltage and current combination to a second power device at a second voltage and current combination, the DC-to-DC converter comprising:
a first electrical conductor having a first end and a second end; and
a second electrical conductor having a third end and a fourth end,
wherein the first end and the third end are electrically coupled to the first power device and wherein the second end and the fourth end are electrically coupled to the second power device,
wherein the first electrical conductor and the second electrical conductor together provide circuit inductance substantially equivalent to and in place of an inductor having a circular winding, and
wherein a length of the first electrical conductor is determined based on an inductance value of the inductor with a circular winding.

20. (canceled)
